(19) United States
(12) Patent Application Publication
(10) Pub. No.: US 2020/0047486 A1
(43) Pub. Date: Feb. 13, 2020

(54) COOLING DEVICE, TEMPERATURE CONTROL DEVICE AND PRINTER

(71) Applicant: Panasonic Intellectual Property Management Co., Ltd., Osaka (JP)

(72) Inventors: TAKAFUMI SHINGAI, Kumamoto (JP); ETSUO KATOU, Fukuoka (JP); TETSUYA NISHIO, Fukuoka (JP); EIJI OKUZONO, Fukuoka (JP)

(21) Appl. No.: 16/344,350

(22) PCT Filed: Oct. 31, 2017
(86) PCT No.: PCT/JP2017/039212

§ 371 Date: Apr. 23, 2019

(30) Foreign Application Priority Data
Nov. 18, 2016 (JP) 2016-224859

(51) Int. Cl. B41F 23/04; H01L 35/30; H01L 35/32; H01L 35/02; B41J 29/377; B41J 11/00; F25B 21/02

(52) U.S. Cl. CPC B41F 23/0476; H01L 35/30; H01L 35/32; F25B 21/02; B41J 29/377; B41J 11/0015; H01L 35/02

(57) ABSTRACT

A cooling device includes a cylindrical body having thermal conductivity, a plurality of thermoelectric converters, and a feeder cable. The plurality of thermoelectric converters are arranged along a periphery of the cylindrical body and disposed dispersedly along an axis of the cylindrical body. The feeder cable connects two or more thermoelectric converters arranged along the periphery of the cylindrical body in series among the plurality of thermoelectric converters to form each of a plurality of sets of thermoelectric converters. And the feeder cable forms a circuit for power feeding of the each of the plurality of sets of thermoelectric converters. A voltage is applied individually to each of circuits that includes the circuit so that thermoelectric converters of the each of the circuits in the plurality of thermoelectric converters are driven.

### TECHNICAL FIELD

The present disclosure relates to a cooling device, a temperature control device, and a printer having the cooling device and the temperature control device.

### BACKGROUND

For performing printing on paper with a printer, the temperature of paper rises significantly by an ink drying operation or the like. Therefore, the printer includes a cooling device for cooling heated paper. When so-called duplex printing is conducted, the printer performs printing on one side of paper, and then feeds the paper to the cooling device in order to lower the temperature of the paper, and then performs printing on the other side. For example, a cooling device of water-cooling type may be installed in a large-sized printer. Further, the printer may include a cooling device using thermoelectric conversion modules constituted by integrating of a plurality of Pertier elements.

Patent Literature 1 discloses a cooling device using thermoelectric conversion modules and a printer provided with the same cooling device. The printer includes a front-side printing apparatus, a dryer for heating and drying ink, a cooling device configured to cool the printing paper to a temperature suitable for applying ink in back-side printing, and a back-side printing apparatus in order from the upstream of a conveyance passage for conveying a belt-shaped printing paper drawn from a roll paper. In the cooling device, the printing paper contacts with an outer peripheral surface of a cylindrical body having a cylindrical shape. A plurality of thermoelectric conversion modules are mounted on an inner peripheral surface of the cylindrical body so as to be arranged in line along an axis of the cylindrical body. Heat of the printing paper is removed by a cooling effect by these thermoelectric conversion modules.

### CITATION LIST

### Patent Literature

PTL 1: Unexamined Japanese Patent Publication No. 2016-107616

### SUMMARY

A first aspect of the present disclosure relates to a cooling device configured to cool an object. The cooling device according to the first aspect includes: a cylindrical body having thermal conductivity; a plurality of thermoelectric converters; and a feeder cable. The plurality of thermoelectric converters are arranged along a periphery of the cylindrical body and disposed dispersedly along an axis of the cylindrical body. The feeder cable connects two or more thermoelectric converters arranged along the periphery of the cylindrical body in series among the plurality of thermoelectric converters to form each of a plurality of sets of thermoelectric converters. And the feeder cable forms a circuit for power feeding of the each of the plurality of sets of thermoelectric converters.

According to the cooling device of this aspect, power feed control can be performed for each of the sets of thermoelectric converters arranged along the periphery of the cylindrical body. Therefore, a cooling capacity of the cooling device may be varied along an axis of the cylindrical body. Accordingly, for example, even when the width of an object changes, the object may be cooled efficiently. Alternatively, the object can be cooled substantially equally even when a temperature change occurs in cooling air flowing along an axis of the cylindrical body. Accordingly, the object can be cooled efficiently and stably.

A second aspect of the present disclosure relates to a cooling device configured to cool an object. The cooling device according to the second aspect includes a cylindrical body having thermal conductivity, and a plurality of thermoelectric converters disposed dispersedly along an axis of the cylindrical body. Here the thermoelectric converters are disposed more densely on a portion at the downstream side of the cooling air flowed along the axis than on a portion at the upstream side.

According to the cooling device of this aspect, since the cooling effect is higher on the downstream side than the upstream side of the cooling air, the temperature of the cooling air rises at the downstream side due to exhaust heat from the thermoelectric converters. Accordingly, even when a cooling capacity of the thermoelectric converters at the downstream side is lowered compared with the upstream side, the cooling effect applied to the cylindrical body may be made substantially equal along an axis of the cylindrical body. Therefore, the object can be cooled substantially equally.

A third aspect of the present disclosure relates to a temperature control device configured to control the temperature of an object. The temperature control device according to the third aspect includes: a cylindrical body having thermal conductivity; a plurality of thermoelectric converters; a feeder cable; a driver; and a polarity switching circuit. The plurality of thermoelectric converters are arranged along a periphery of the cylindrical body and disposed dispersedly along an axis of the cylindrical body. The feeder cable connects two or more thermoelectric converters arranged along the periphery of the cylindrical body in series among the plurality of thermoelectric converters to form each of a plurality of sets of thermoelectric converters. The feeder cable forms a circuit for power feeding of the each of the plurality of sets of the thermoelectric converters. The driver is configured to feed power to the plurality of thermoelectric converters via the feeder cables. The polarity switching circuit is configured to electrically change a power feed polarity for the circuit.

According to the temperature control device of this aspect, both the cooling effect and the heating effect can be applied to the cylindrical body by changing the power feed polarity by the polarity switching circuit. When the cooling effect is applied to the cylindrical body, the same advantageous effects as in the first aspect may be achieved. Likewise, when the heating effect is applied to the cylindrical body, a heating performance of the temperature control device may be varied along an axis of the cylindrical body. Accordingly, for example, even when the width of an object changes, the object may be heated efficiently. Alternatively, the object can be heated substantially equally even when a temperature change occurs in cooling air flowing along an axis of the cylindrical body. Accordingly, the object can be heated efficiently and stably. In addition, in the case where the cylindrical body does not reach a predetermined temperature or higher when power is turned ON, the cylindrical body can be heated rapidly to a temperature close to a proper temperature.

A fourth aspect of the present disclosure relates to a printer. The printer according to the fourth aspect includes: the cooling device according to the first aspect or the second aspect, a printing section configured to perform printing on a sheet-shaped material to be printed, the sheet-shaped material being an object, and a conveying section configured to convey the sheet-shaped material to be printed from the printing section to the cooling device.

According to the printer of the fourth aspect, since the cooling device according to the first aspect or the second aspect is provided, the sheet-shaped material to be printed, the sheet-shaped material being an object, can be cooled efficiently and stably.

A fifth aspect of the present disclosure relates to a printer. The printer according to the fifth aspect includes: the temperature control device according to the third aspect, a printing section configured to perform printing on a sheet-shaped material to be printed, the sheet-shaped material being an object, and a conveying section configured to convey the sheet-shaped material to be printed from the printing section to the cooling device.

According to the printer of the fifth aspect, since the temperature control device according to the third aspect is provided, the sheet-shaped material to be printed, the sheet-shaped material being an object, can be cooled and heated efficiently and stably.

As described thus far, according to the present disclosure, a cooling device capable of cooling an object efficiently and stably, and a printer having the cooling device can be provided.

Effects or meanings of the present disclosure will be further clarified in the following description of an exemplary embodiment. However, the exemplary embodiment described below is merely an example of implementing the present disclosure, and the present disclosure is not at all limited to the examples described in the following exemplary embodiment.

### BRIEF DESCRIPTION OF DRAWINGS

FIG. 1 is a view schematically illustrating a configuration of a printer according to an exemplary embodiment.

FIG. 2A is a plan view schematically illustrating a configuration of a cooling unit according to the exemplary embodiment.

FIG. 2B is a plan view schematically illustrating a conveying process for printing paper in a cooling unit according to the exemplary embodiment.

FIG. 2C is a plan view schematically illustrating a conveying process for printing paper in a cooling unit according to the exemplary embodiment.

FIG. 3A is a view schematically illustrating the cooling unit according to the exemplary embodiment in a state as seen from a cooling air inlet port side.

FIG. 3B is an exploded perspective view schematically illustrating a configuration of a structure to be mounted on the cooling unit according to the exemplary embodiment.

FIG. 4A is an exploded perspective view schematically illustrating a configuration of a thermoelectric converter according to the exemplary embodiment.

FIG. 4B is a perspective view schematically illustrating a configuration of a thermoelectric converter according to the exemplary embodiment in a state of being completely assembled.

FIG. 5A is a view schematically illustrating a connecting state of feeder cables in a cooling unit according to a comparative example.

FIG. 5B is a graph schematically showing a cooling capacity when the cooling unit according to the comparative example is used.

FIG. 5C is a plan view schematically illustrating a conveying process for printing paper in a cooling unit according to the comparative example.

FIG. 6A is a view schematically illustrating a connecting state of feeder cables in a cooling unit according to the exemplary embodiment.

FIG. 6B is a view schematically illustrating a connecting state of the feeder cables in the cooling unit according to the exemplary embodiment.

FIG. 7A is a view schematically illustrating a connecting state of the feeder cables in the cooling unit according to the exemplary embodiment.

FIG. 7B is a graph schematically showing a cooling capacity when the cooling unit according to the exemplary embodiment is used.

FIG. 7C is a graph schematically showing a cooling capacity when the cooling unit according to the exemplary embodiment is used.

FIG. 8A is a block diagram illustrating a configuration of the printer according to the exemplary embodiment.

FIG. 8B is a flowchart illustrating control of the cooling unit in the printer according to the exemplary embodiment.

FIG. 9A is a view schematically illustrating a connecting state of feeder cables in a cooling unit according to a first modified example.

FIG. 9B is a view schematically illustrating a connecting state of feeder cables in a cooling unit according to a second modified example.

FIG. 10A is a view schematically illustrating a connecting state of feeder cables in a cooling unit according to a third modified example.

FIG. 10B is a view schematically illustrating a connecting state of feeder cables in a cooling unit according to a fourth modified example.

FIG. 11A is a graph schematically showing setting voltages to be applied and a cooling capacity in the cooling unit according to a fifth modified example.

FIG. 11B is a view schematically illustrating a configuration of a temperature control device and a connecting state of feeder cables according to a sixth modified example.

FIG. 12A is a plan view schematically illustrating a conveying process for printing paper in a cooling unit according to the sixth modified example.

FIG. 12B is a plan view schematically illustrating a conveying process for printing paper in the cooling unit according to the second modified example.

### DESCRIPTION OF EMBODIMENT

Prior to description of an exemplary embodiment of the present disclosure, problems found in conventional techniques will briefly be described. In general, in the cooling device having the configuration described above, the thermoelectric conversion modules arranged along an axis of the cylindrical body are connected in series, and driving control is performed for each of the thermoelectric conversion modules.

However, in this connecting state, for example, when the width of printing paper is significantly smaller than the width of the cylindrical body, a cooling effect is applied also to a region where the printing paper does not contact (non sliding contact region). In this case, power consumed by cooling the non-contact region is wasted. In addition, dew condensation may occur in the non-contact region because the non-contact region is excessively cooled. When condensed dew is attached to printing paper, blur of printing or damage to printing paper may occur.

Further, when heat is exhausted from the thermoelectric conversion modules by feeding air into an interior of the cylindrical body, the temperature of air flowing in the interior of the cylindrical body rises gradually. Accordingly, the cooling capacity of the thermoelectric conversion modules positioned at the downstream side of the air flow is lowered compared with that of the thermoelectric conversion modules at the upstream side. Therefore, unevenness in temperature along the width of the printing paper may occur after cooling.

When the printer is used in cold areas, the temperature of the cooling device may not reach a predetermined temperature or more after the power of the printer is turned ON. In this case, it is preferable that the cylindrical body is rapidly heated to a proper temperature. Consequently, time needed until the start of printing after the power of the printer is turned ON may be reduced. In such a case, a temperature control device having not only a function to cool the cylindrical body, but also a function to heat the cylindrical body may be mounted on the printer instead of the cooling device. In this temperature control device as well, the problem of wasted power consumption and unevenness of the temperature may occur in the same manner as the cooling device descried above.

In view of such a problem, the present disclosure provides a cooling device capable of cooling an object efficiently and stably, a temperature control device capable of cooling and heating the object efficiently and stably, and a printer provided with the cooling device and the temperature control device.

An exemplary embodiment of the present disclosure will be described below with reference to the accompanying drawings. For convenience, X, Y and Z-axes perpendicular to one another are added to respective drawings.

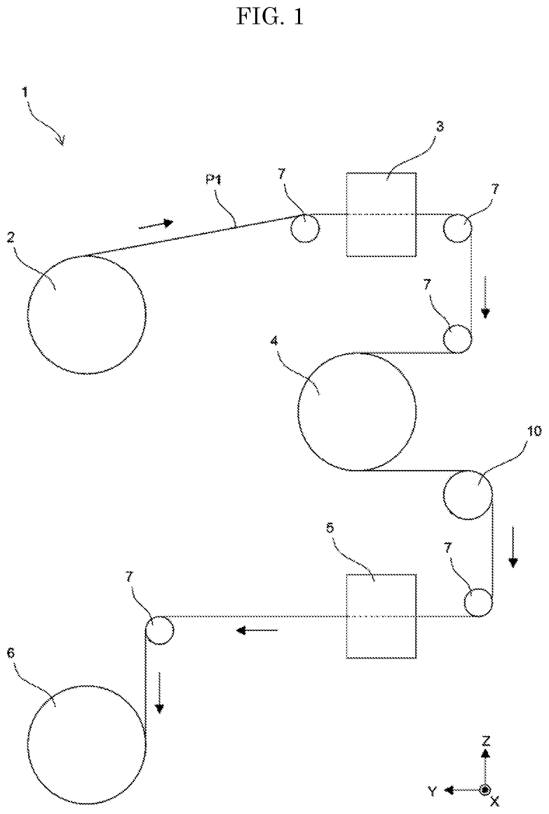

FIG. 1 is a view schematically illustrating a configuration of printer 1. FIG. 1 illustrates a configuration example of industrial printer 1. Printer 1 is not limited to the industrial printer, and may be a consumer printer.

Printer 1 includes front side printing unit 3, dryer 4, and back side printing unit 5 which are disposed along a conveyance passage. On the conveyance passage, printing paper P1 having a belt shape and drawn from roll paper 2 is conveyed. Front side printing unit 3 performs printing on a front side of printing paper P1. Dryer 4 heats and dries ink that is transferred from front side printing unit 3 to printing paper P1. Back side printing unit 5 performs printing on a back side of printing paper P1. Printed printing paper P1 is taken up by winding unit 6. Printing paper P1 is guided by rollers 7 to each part.

It should be noted that the object to be printed does not necessarily have to be paper, and may be other sheet-shaped material to be printed such as cloth. As described later, printing paper P2 having a smaller width in an X-axis direction than that of printing paper P1 may also be supplied to printer 1.

Furthermore, printer 1 includes cooling unit 10 between dryer 4 and back side printing unit 5. Cooling unit 10 cools printing paper P1 heated by dryer 4 to a temperature suitable for applying ink in back-side printing. Cooling unit 10 has a cylindrical shape. Cooling unit 10 rotates about an axis parallel to the X axis with printing paper P1 in contact with an outer peripheral surface. Printing paper P1 is cooled by contacting the outer peripheral surface of cooling unit 10.

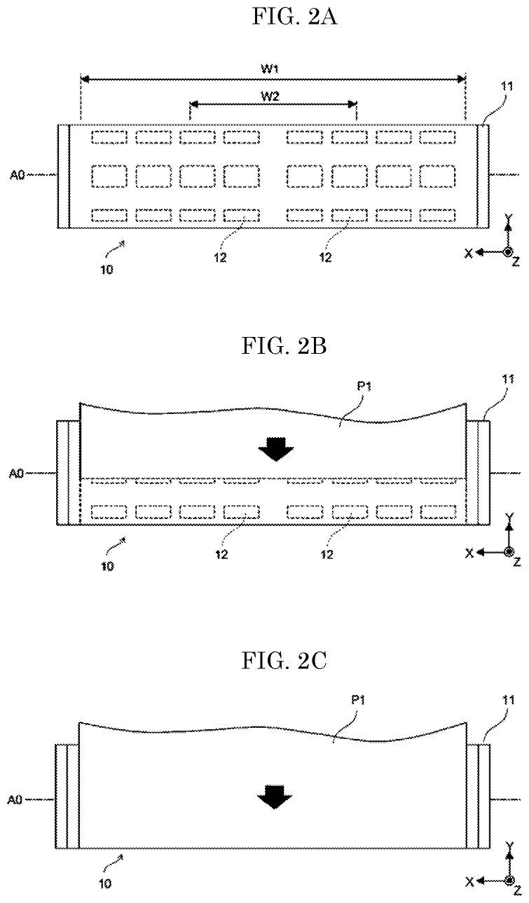

FIG. 2A is a plan view schematically illustrating a configuration of cooling unit 10. For convenience, in FIG. 2A, the configuration of a mechanical portion for rotating cylindrical body 11 about an axis parallel to the X-axis is omitted.

Cooling unit 10 includes cylindrical body 11 and a plurality of thermoelectric converters 12. Cylindrical body 11 has a cylindrical shape and openings respectively at an X-axis positive side and an X-axis negative side. Cylindrical body 11 is made of a material having excellent thermal conductive property such as copper, aluminum, or iron. A plurality of thermoelectric converters 12 are installed on an inner peripheral surface of cylindrical body 11.

Thermoelectric converters 12 are arranged along a periphery of cylindrical body 11 and disposed dispersedly along an axis (X-axis) of cylindrical body 11. In the present exemplary embodiment, thermoelectric converters 12 are arranged along the X-axis. FIG. 2A illustrates a configuration in which eight thermoelectric converters 12 are arranged along the X-axis. However, the number of thermoelectric converters 12 arranged along the X-axis is not limited thereto.

In the present exemplary embodiment, sets of thermoelectric converters 12 in each of which a plurality of thermoelectric converters are arranged along the X-axis are equally disposed along a periphery of cylindrical body 11. The number of sets of thermoelectric converters 12 arranged along a periphery of cylindrical body 11 is, for example, six, but is not limited thereto. The sets of thermoelectric converters 12, each of which is aligned along the X-axis, do not necessarily have to be disposed all around the inner peripheral surface of cylindrical body 11. Furthermore, the sets of the thermoelectric converters 12, each of which is aligned along the X-axis, do not have to be arranged equidistantly along a periphery of cylindrical body 11.

Individual thermoelectric converters 12 have the same configuration and function as one another. Thermoelectric converters 12 cool the inner peripheral surface of cylindrical body 11 by being applied with a voltage. Therefore, when printing paper P1 contacts the outer peripheral surface of cylindrical body 11, heat of printing paper P1 is transferred from the outer peripheral surface to the inner peripheral surface of cylindrical body 11, and further to thermoelectric converters 12. Accordingly, printing paper P1 is cooled.

It should be noted that, in FIG. 2A, W1 indicates a width of contact of printing paper P1 with cylindrical body 11 when printing paper P1 is supplied to cooling unit 10. W2 indicates a width of contact of printing paper P2 described later with cylindrical body 11 when printing paper P2 is supplied to cooling unit 10.

FIGS. 2B and 2C are plan views schematically illustrating a conveying process for printing paper P1 in cooling unit 10. For convenience, FIG. 2B illustrates a state in which a Y-axis negative side of printing paper P1 is seen through.

Printing paper P1 is wound around the outer peripheral surface of cylindrical body 11 from a Y-axis positive side, and is carried in a Z-axis negative direction. In the conveying process, cylindrical body 11 rotates about an axis parallel to the X-axis with printing paper P1 being carried. Accordingly, the outer peripheral surface of cylindrical body 11 contacts with printing paper P1 in sequence. Printing paper P1 is cooled by thermoelectric converters 12 while being wound around the outer peripheral surface of cylindrical body 11. During this operation, by changing the method of conveyance of printing paper P1 so that the direction of conveyance of printing paper P1 is redirected from Z-axis negative direction to Y-axis positive direction, cooling efficiency by thermoelectric converters 12 is enhanced because printing paper P1 wound around the outer peripheral surface of cylindrical body 11 for a longer distance.

It should be noted that the heat transferred from printing paper P1 to thermoelectric converters 12 is exhausted by cooling air flowing into an interior of cylindrical body 11. The cooling air is supplied into the interior of cylindrical body 11 by a blower, not illustrated. The cooling air flows from an opening (inlet port) at X-axis positive side of cylindrical body 11, and flows out from an opening (outlet port) at X-axis negative side of cylindrical body 11.

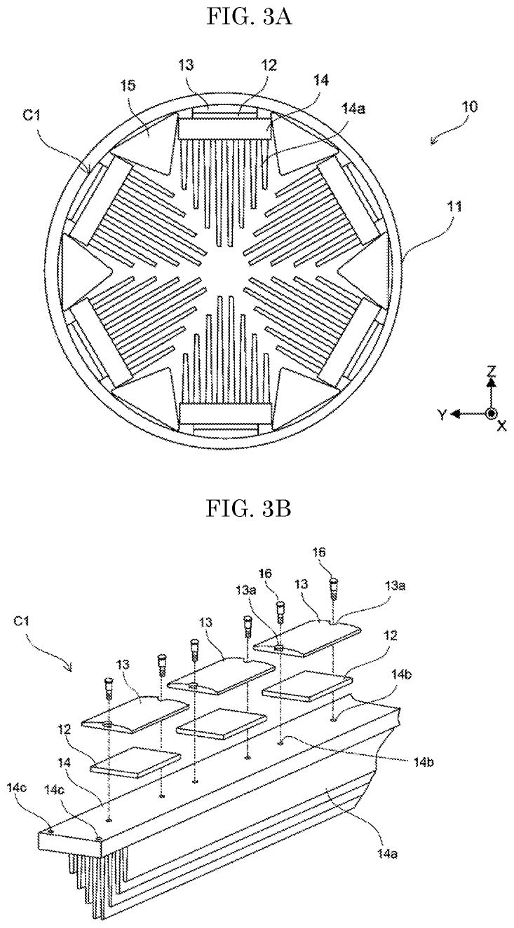

FIG. 3A is a view schematically illustrating cooling unit 10 as seen from a cooling air inlet port side. FIG. 3B is an exploded perspective view schematically illustrating a configuration of structure C1 to be mounted on cooling unit 10.

As illustrated in FIG. 3A, six structures C1 are uniformly mounted on the inner peripheral surface of cylindrical body 11. In addition, spacers 15 are disposed to fill spaces between one structure C1 and adjacent structures C1. In this configuration, a larger amount of cooling air may be directed toward heatsink 14.

As illustrated in FIG. 3B, structure C1 includes thermoelectric converters 12, presser plates 13, and heatsink 14. Upper surfaces of presser plates 13 curve in conformity with the inner peripheral surface of cylindrical body 11, and have an arcuate shape. Presser plates 13 are fixed to heatsink 14 with screws 16 with thermoelectric converters 12 disposed between an upper surface of heatsink 14 and lower surfaces of presser plates 13. Presser plates 13 have holes 13a for allowing insertion of screws 16, and heatsink 14 has screw holes 14b for allowing screws 16 to be screwed in. Screws 16 are screwed into screw holes 14b through holes 13a. In this manner, thermoelectric converters 12 are mounted on the upper surface of heatsink 14.

It should be noted that only three thermoelectric converters 12 are illustrated in FIG. 3B because a portion near a front end of heatsink 14 is illustrated. Heatsink 14 has a shape extending further rearward. Eight thermoelectric converters 12 in total are mounted on the upper surface of heatsink 14 in the similar configuration as illustrated in FIG. 3B.

Heatsink 14 and presser plates 13 are made of a material having excellent thermal conductive property such as copper, aluminum, and the like. Presser plates 13 are a thin plate-shaped member. Heatsink 14 is a plate-shaped member having a predetermined thickness, and has a rectangular shape. The lower surface of heatsink 14 is provided with a plurality of plate-shaped fins 14a in parallel to each other. In addition, heatsink 14 is provided with screw holes 14c penetrating from the top to the bottom at a front end and a rear end.

As illustrated in FIG. 3A, screws (not illustrated) are anchored from an outer peripheral surface side of cylindrical body 11 in screw holes 14c in heatsink 14 in a state in which six structures C1 are arranged on an inner peripheral surface of cylindrical body 11. Cylindrical body 11 is also provided with holes (not illustrated) for screwing screws into screw holes 14c. In this manner, as illustrated in FIG. 3A, six structures C1 are mounted on the inner peripheral surface of cylindrical body 11 evenly along the periphery of the cylindrical body 11.

The cooling air flowed into cylindrical body 11 passes through gaps between fins 14a and is discharged from cylindrical body 11. Accordingly, heat transferring from thermoelectric converters 12 to fins 14a is removed. Accordingly, accumulation of heat on heat dissipating surfaces of thermoelectric converters 12 is suppressed, and cooling effect in thermoelectric converters 12 is maintained.

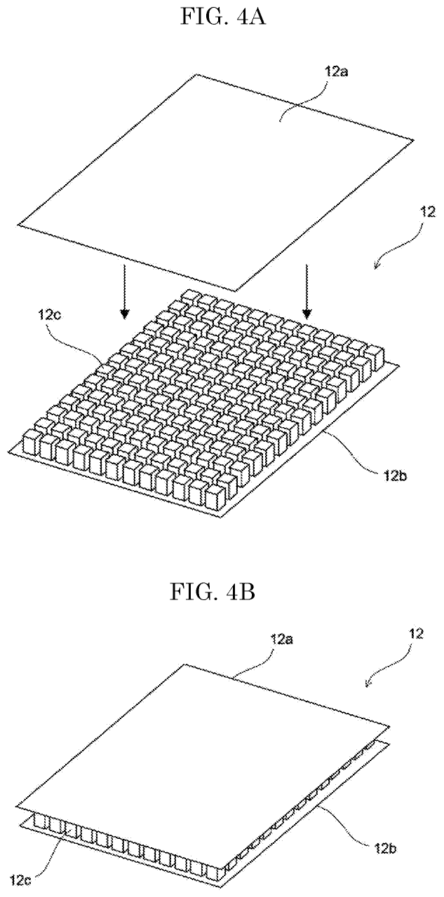

FIG. 4A is an exploded perspective view schematically illustrating a configuration of thermoelectric converter 12, and FIG. 4B is a perspective view schematically illustrating a configuration of thermoelectric converter 12 in a state of being completely assembled.

As illustrated in FIG. 4A, thermoelectric converter 12 includes first substrate 12a, second substrate 12b, and thermoelectric conversion elements 12c.

First substrate 12a and second substrate 12b have a substantially rectangular shape in plan view, and are formed of metallic material having a high thermal conductivity. As illustrated in FIG. 4A, first substrate 12a is overlapped on upper surfaces of thermoelectric conversion elements 12c in a state in which thermoelectric conversion elements 12c are disposed on an upper surface of second substrate 12b. Thermoelectric conversion elements 12c are arranged in an X-axis direction and in a Y-axis direction at constant pitches. Thermoelectric conversion elements 12c are elements for transferring heat based on an applied voltage and cooling such as Pertier elements.

It should be noted that a lower surface of first substrate 12a and an upper surface of second substrate 12b are respectively provided with connection electrodes (not illustrated). The connection electrodes are joined to upper electrodes and lower electrodes on thermoelectric conversion elements 12c. Voltage is applied to thermoelectric conversion elements 12c via these connection electrodes. The connection electrode formed on first substrate 12a and the connection electrode formed on second substrate 12b are set such that a voltage is applied to all thermoelectric conversion elements 12c uniformly when a voltage is applied from a terminal not illustrated to thermoelectric converter 12 assembled as illustrated in FIG. 4B.

For assembly, thermoelectric conversion elements 12c are disposed as illustrated in FIG. 4A in a state in which solder is applied to the connection electrode on the upper surface of second substrate 12b. In addition, first substrate 12a is placed on the upper surfaces of thermoelectric conversion elements 12c as illustrated in FIG. 4B in a state in which solder is applied to the connection electrode on the lower surface of first substrate 12a. In this state, a reflow process is performed for welding solder. Accordingly, the respective connection electrodes are joined to thermoelectric conversion elements 12c, so that first substrate 12a and second substrate 12b are secured. In this manner, thermoelectric converter 12 is constructed as illustrated in FIG. 4B. When a voltage is applied to thermoelectric converter 12, heat of a cooling surface (upper surface of first substrate 12a) of thermoelectric converter 12 transfers to a heat generating surface (lower surface of second substrate 12b) of thermoelectric converter 12.

Next, a connecting state of feeder cables in cooling unit 10 of the present exemplary embodiment will be described with reference to a comparative example.

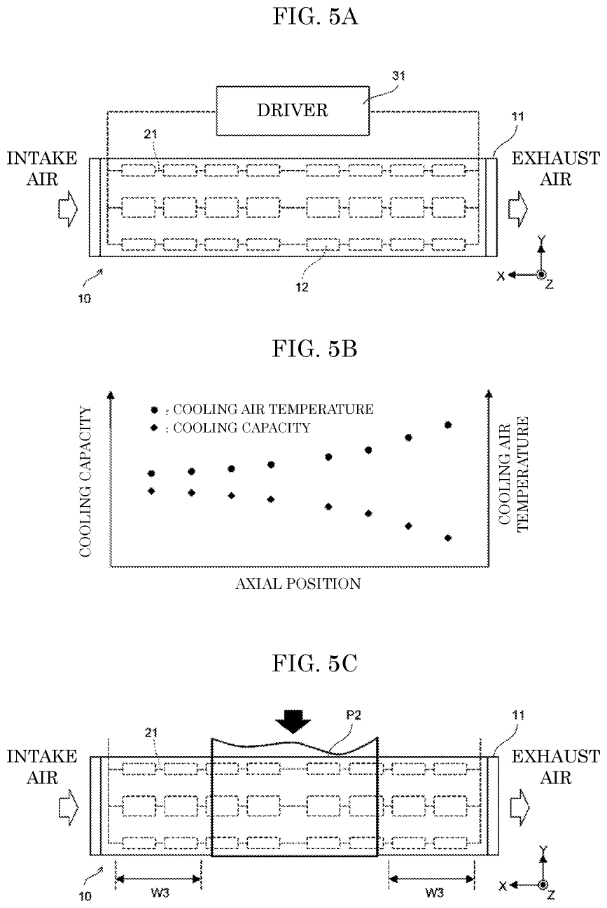

FIG. 5A is a view schematically illustrating a connecting state of feeder cables in cooling unit 10 according to the comparative example.

As illustrated in FIG. 5A, in the comparative example, eight thermoelectric converters 12 arranged along an axis (X-axis) of cylindrical body 11 are connected in series by feeder cables 21. In other words, eight thermoelectric converters 12 included in one structure C1 illustrated in FIG. 3B are connected in series. Six sets of eight thermoelectric converters 12 connected in series are provided along the periphery of the cylindrical body 11. Driver 31 applies voltages individually to six sets of thermoelectric converters 12 connected in series. Voltages may be applied from driver 31 in parallel to six sets of thermoelectric converters 12. Driver 31 and feeder cables 21 are connected, for example, via a brush disposed on a rotary shaft of cylindrical body 11.

In the connecting state in the comparative example, currents respectively flowing through eight thermoelectric converters 12 arranged along the axis (X-axis) of cylindrical body 11 are identical. Therefore, driving of thermoelectric converters 12 cannot be controlled for each position along the axis (X-axis) of cylindrical body 11. In the comparative example, control for each set of eight thermoelectric converters 12 arranged along the axis (X-axis) of cylindrical body 11 is performed. Therefore, in the comparative example, temperature gradient may arise along the axis (X-axis) in cylindrical body 11 as described below.

FIG. 5B is a graph schematically illustrating a cooling capacity when cooling unit 10 according to the comparative example is used.

As illustrated in FIG. 5A, when cooling air is introduced from an opening (inlet port) at the X-axis positive side of cylindrical body 11, cooling air absorbs heat from fins 14a during passage through the interior of cylindrical body 11. Therefore, temperature of the cooling air rises as the position along the axis shifts in the X axis negative direction as indicated by plots of black circles in FIG. 5B. When the temperature of cooling air rises, the heat quantity transferring from fins 14a to the cooling air decreases. Therefore, the temperature of the heat generating surface of thermoelectric converter 12 (the lower surface of second substrate 12b illustrated in FIG. 4B) rises, and the cooling capacity of thermoelectric converter 12 is lowered. Therefore, the cooling capacity of thermoelectric converter 12 is lowered as the position along the axis is shifted in the X axis negative direction as indicated by plots of black rhombus in FIG. 5B.

In this manner, in the connecting state of the comparative example, the cooling capacities of eight thermoelectric converters 12, each of which is aligned along the axis (X-axis) of cylindrical body 11 are not equal, and thus uneven cooling occurs in the same tendency as the graph of black rhombus in FIG. 5B also in cylindrical body 11. Accordingly, temperature gradient occurs in cylindrical body 11. Therefore, temperature gradient occurs along a width (X-axis) of printing paper P1 that contacts with cylindrical body 11. The temperature gradient of printing paper P1 may impair printing in back side printing unit 5 illustrated in FIG. 1.

When printing paper P2 having a width smaller than that of printing paper P1 is supplied to cooling unit 10 according to comparative example, problems of dew condensation or power loss may arise.

FIG. 5C is a plan view schematically illustrating a conveying process for printing paper P2 in cooling unit 10 according to the comparative example. It should be noted that a state in which printing paper P2 is seen through is illustrated.

When printing paper P2 having small width is supplied to cooling unit 10, printing paper P2 does not contact with regions W3 on both sides of printing paper P2. However, in the comparative example, eight thermoelectric converters 12, each of which is aligned along the axis (X-axis) are connected in series, and thus a current also flows through thermoelectric converters 12 included in regions W3 (non-contact regions) in the same manner as central thermoelectric converter 12 to apply a cooling effect to cylindrical body 11. Therefore, cylindrical body 11 is excessively cooled in regions W3 (non-contact regions), and consequently, dew condensation may occur on the outer peripheral surface of cylindrical body 11 in regions W3. When condensed dew is attached to printing paper, blur of printing or damage to printing paper may occur. In addition, power consumed by cooling of regions W3 is wasted.

As described above, in the connecting state of the comparative example, various problems may occur in cooling of printing papers P1, P2. In contrast, in the present exemplary embodiment, the connecting state of the feeder cables in cooling unit 10 is different from that of the comparative example.

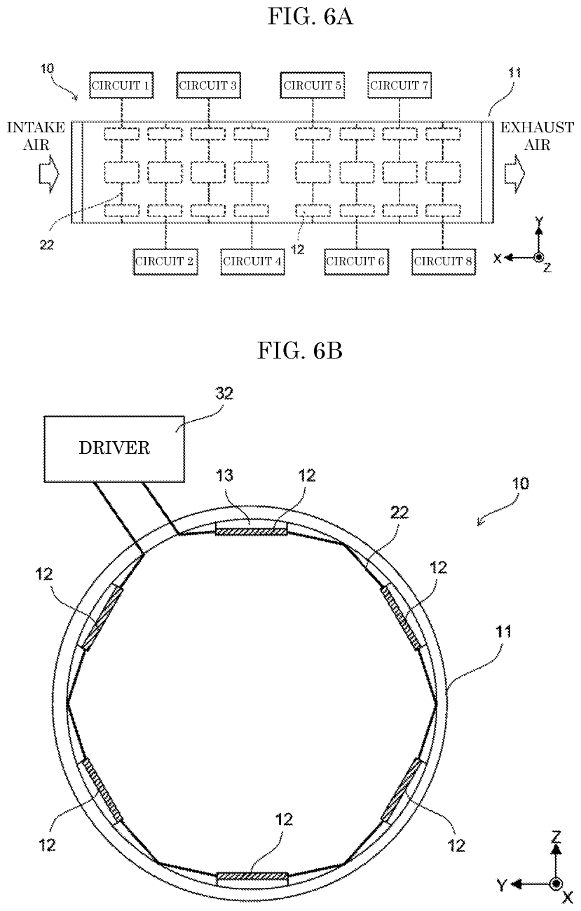

FIGS. 6A and 6B are views schematically illustrating a connecting state of feeder cables 22 in cooling unit 10 according to the exemplary embodiment. FIG. 6A is a view of cooling unit 10 as seen from a Z-axis positive side, and FIG. 6B is a view of cooling unit 10 as seen from the X-axis positive side. For convenience, illustration of a configuration of cylindrical body 11 on the central axis side with respect to thermoelectric converters 12 is omitted in FIG. 6B. As illustrated in FIGS. 6A and 6B, in the exemplary embodiment, six thermoelectric converters 12 arranged along the periphery (around X-axis) of cylindrical body 11 are connected in series by feeder cables 22. In other words, six thermoelectric converters 12 arranged along the periphery (around X-axis) of cylindrical body 11 are connected in series to form one circuit. Eight circuits including six thermoelectric converters 12 connected in series are disposed along the axis (X-axis). Driver 32 applies voltages to the respective circuits individually. Driver 32 and feeder cables 22 are connected, for example, via a brush disposed on a rotary shaft of cylindrical body 11.

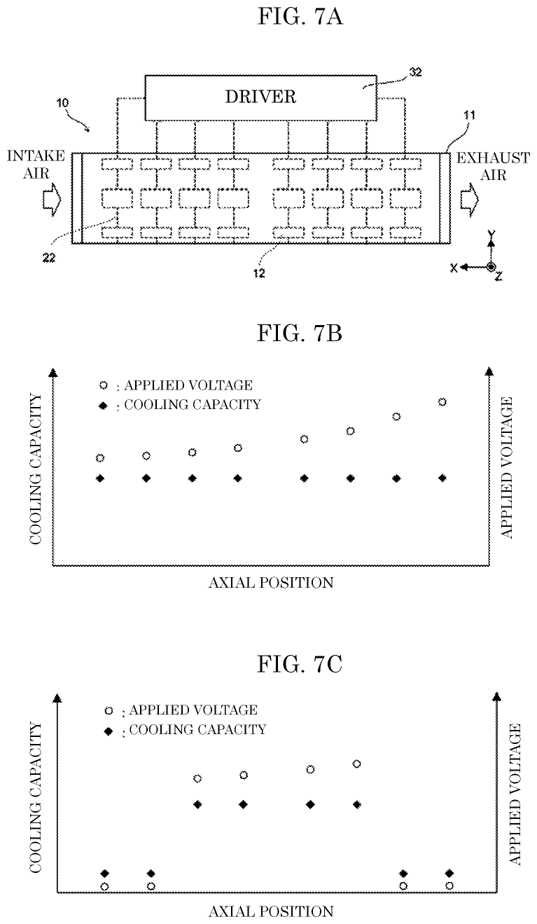

FIG. 7A is a view schematically illustrating a connecting state of the feeder cables in cooling unit 10 according to the exemplary embodiment.

In the connecting state in the exemplary embodiment, currents respectively flowing six thermoelectric converters 12 arranged along a periphery (around X-axis) of cylindrical body 11, which are included in the circuit, are identical. However, the voltages to be applied may be differentiated from circuit to circuit. Therefore, driving of thermoelectric converters 12 can be controlled for each position along the axis (X-axis) of cylindrical body 11. Accordingly, in the exemplary embodiment, temperature gradient along the axis (X-axis) in cylindrical body 11 may be suppressed.

FIGS. 7B and 7C are graphs schematically illustrating a cooling capacity when cooling unit 10 according to the exemplary embodiment is used.

As described with reference to FIG. 5B, the cooling capacities of thermoelectric converters 12 are lowered as the position along the axis shifts in the X axis negative direction due to an increase in temperature of cooling air in an interior of cylindrical body 11. Accordingly, in the present exemplary embodiment, voltages to be applied to the respective circuits, each including six thermoelectric converters 12 arranged along the periphery, are differentiated as indicated by plots of open circles in FIG. 7B. In other words, driver 32 increases the voltages to be applied to the circuit as the position goes toward the downstream side (X-axis negative side) of cooling air to enhance the cooling capacity of thermoelectric converters 12. Accordingly, as indicated by the plots of the black rhombus in FIG. 7B, the cooling capacities of thermoelectric converters 12 becomes substantially equal along the axis (X-axis) of cylindrical body 11. In this manner, in the present exemplary embodiment, uneven cooling of cooling unit 10 is suppressed.

As described with reference to FIG. 5C, when printing paper P2 having a smaller width is supplied to cooling unit 10, printing paper P2 does not contact with the outer peripheral surface of cylindrical body 11 in regions W3 on both sides of printing paper P2. Therefore, in the exemplary embodiment, as illustrated in FIG. 7C, the voltage to be applied to thermoelectric converters 12 included in regions W3 is lowered compared with the voltage applied to thermoelectric converters 12 included in a central region where printing paper P2 contacts. For example, driver 32 stops application of voltage to thermoelectric converters 12 included in regions W3 (applied voltage=0). Alternatively, driver 32 lowers voltages to be applied to thermoelectric converters 12 included in regions W3 to voltages near zero. Accordingly, an occurrence of dew condensation is suppressed on cooling unit 10 in regions W3 due to excessively cooling of regions W3. In addition, wasted power consumption in regions W3 may be avoided.

It should be noted that, in this exemplary embodiment, thermoelectric converters 12 included in the central region where printing paper P2 contacts may or may not include thermoelectric converters 12 disposed so as to partly overlap the central region.

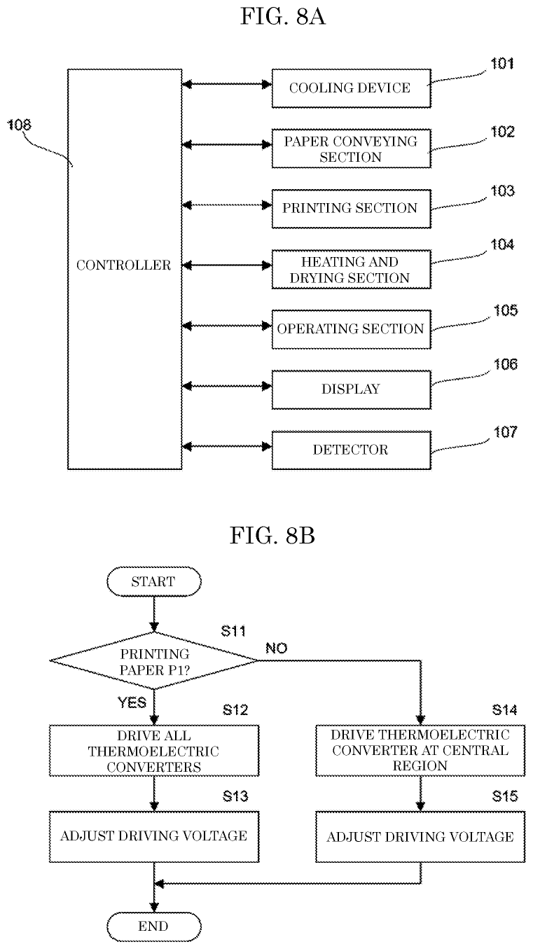

FIG. 8A is a block diagram illustrating a configuration of printer 1.

Printer 1 is provided with cooling device 101, paper conveying section 102, printing section 103, heating and drying section 104, operating section 105, display 106, detector 107, and controller 108.

Cooling device 101 includes cooling unit 10, feeder cables 22, and driver 32 as illustrated in FIGS. 2A to 4B and FIGS. 6A to 7A. Paper conveying section 102 includes roll paper 2, winding unit 6, rollers 7, and a motor as a drive source illustrated in FIG. 1. Printing section 103 includes front side printing unit 3 and back side printing unit 5 illustrated in FIG. 1. Heating and drying section 104 includes dryer 4 illustrated in FIG. 1. Operating section 105 includes input means such as a touch panel, a keyboard, and the like. Display 106 includes display means such as a liquid crystal monitor. Detector 107 includes various sensors such as a sensor for detecting the width of printing paper, a sensor for detecting a conveying position of printing paper, and a temperature sensor configured to measure a temperature of cylindrical body 11 and temperatures of printing papers P1, P2.

Controller 108 includes an arithmetic processing circuit such as a central processing unit (CPU), and storage media such as a read only memory (ROM), a random access memory (RAM), a hard disk. Controller 108 controls various sections in accordance with a program stored in the storage media.

FIG. 8B is a flowchart illustrating control of cooling device 101.

Controller 108 determines whether target paper for printing set in printer 1 is printing paper P1 or P2 based on a detection signal from detector 107 (S11). When target paper for printing is printing paper P1 (Yes in S11), controller 108 controls driver 32 to drive all thermoelectric converters 12 mounted on cooling unit 10 (S12). In this case, driver 32 adjusts voltages to be applied to the respective circuits illustrated in FIG. 6A as indicated in FIG. 7B (S13).

In contrast, when target paper for printing is printing paper P2 (No in S11), controller 108 controls driver 32 to drive only thermoelectric converters 12 included in the central region excluding regions W3 illustrated in FIG. 5C among thermoelectric converters 12 mounted on cooling unit 10 (S14). In this case, driver 32 adjust voltages to be applied to respective circuits illustrated in FIG. 6A as indicated in FIG. 7C (S15). In control indicated in FIG. 7C, in the central region excluding regions W3, the voltages applied to the circuits are higher as it goes toward the X-axis negative side.

It should be noted that although two widths of target paper for printing are assumed in the present exemplary embodiment, when three or more widths of target paper for printing are used, the range of thermoelectric converters 12 to be driven are set according to the respective widths. In other words, thermoelectric converters 12 included in a range of each width are driven and thermoelectric converters 12 not included in the range of each width are not driven. In this case as well, thermoelectric converters 12 not included in the ranges of the widths may be adapted to be driven at a voltage near zero.

### Effects of Exemplary Embodiment

As stated above, the present exemplary embodiment exerts the following effects.

Power feed control can be performed for each of thermoelectric converters 12 arranged along the periphery. Therefore, a cooling capacity of cooling unit 10 may be varied along the axis of cylindrical body 11. Accordingly, for example, even when the width of a printing object changes, the printing object may be cooled efficiently. Alternatively, the printing object can be cooled substantially equally even when a temperature change occurs in cooling air flowing along the axis of cylindrical body 11. Accordingly, the printing object can be cooled efficiently and stably.

As illustrated in FIG. 7B, driver 32 sets a voltage to be applied to thermoelectric converters 12 positioned on the downstream side of cooling air flowed along the axis (X-axis) of cylindrical body 11 to be higher than a voltage for thermoelectric converters 12 positioned on the upstream side of the cooling air. Accordingly, even when the temperature of the cooling air rises while flowing in the interior of cylindrical body 11, the cooling capacities of thermoelectric converters 12 may be made substantially equal. Accordingly, in cylindrical body 11, generation of the temperature gradient along the axis may be suppressed.

As illustrated in FIG. 7C, driver 32 sets a voltage to be applied to thermoelectric converters 12 positioned within a range of the width of printing paper P2 along the axis (X-axis) of cylindrical body 11 to be higher than a voltage for thermoelectric converters 12 positioned out of the range of the width of printing paper P2. For example, driver 32 stops the power feeding to thermoelectric converters 12 positioned out of the range of the width of printing paper P2. Accordingly, an occurrence of such an event that cooling unit 10 excessively cools in regions W3 where printing paper P2 does not contact is suppressed. Such excessive cooling may cause dew condensation on the outer peripheral surface of cylindrical body 11. In addition, wasted power consumption in regions W3 may be avoided.

### FIRST MODIFIED EXAMPLE

The exemplary embodiment of the present disclosure has been described. The scope of the present disclosure, however, should not be limited to the exemplary embodiment.

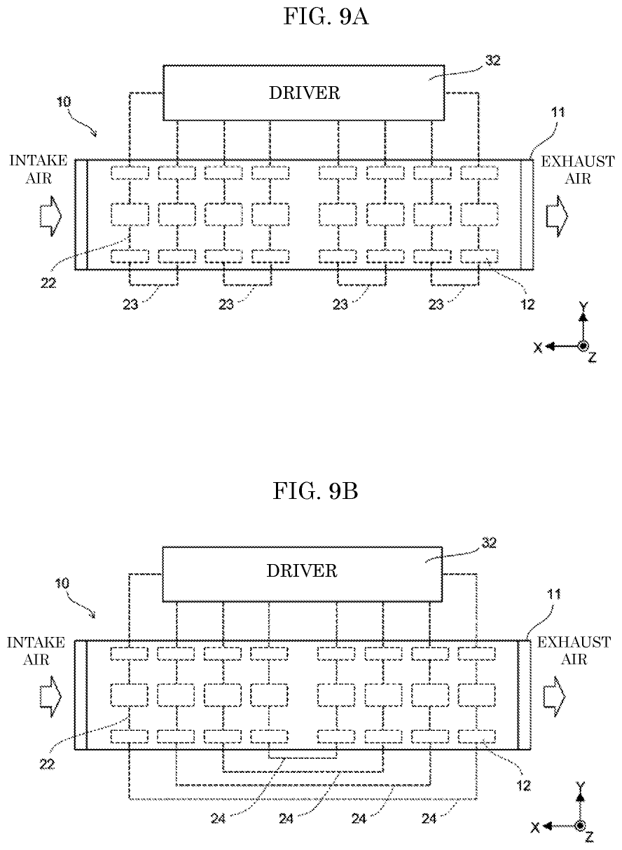

For example, in the exemplary embodiment described above, the circuits are formed by connecting six thermoelectric converters 12 arranged along the periphery in series and voltages are applied from driver 32 individually to the circuits as illustrated in FIG. 7A. However, two circuits each from an end of cylindrical body 11 along the axis may be combined as a set to constitute secondary circuits, and voltages may be applied from driver 32 individually to the secondary circuits as illustrated in a first modified example in FIG. 9A. In the configuration illustrated in FIG. 9A, six thermoelectric converters 12 arranged along the periphery are connected in series by feeder cables 22 to constitute a primary circuit, and two each of primary circuits adjacent to each other are connected by feeder cables 23 in series to constitute the secondary circuit. In other words, twelve thermoelectric converters 12 in total are connected in series to constitute the secondary circuit, and driver 32 applies voltages individually to the secondary circuits.

With the configuration of the first modified example as well, power feed control can be performed for each set including a first set of six thermoelectric converters 12 arranged along the periphery and a second set of six thermoelectric converters 12 arranged adjacent along the X-axis to the first set of thermoelectric converters 12, so that cooling capacity of cooling unit 10 may be varied along the axis of cylindrical body 11. However, since two primary circuits are controlled together, the widthwise range in the X-axis direction in which the cooling capacity can be varied is increased compared with the exemplary embodiment described above. According to the configuration of the first modified example, the number of feeder cables to be drawn from cylindrical body 11 to driver 32 may be reduced compared with the exemplary embodiment described above.

It should be noted that, in the configuration illustrated in FIG. 9A, two primary circuits adjacent to each other are connected in series to constitute secondary circuits. However, two primary circuits adjacent to each other may be connected in parallel to constitute the secondary circuits. Alternatively, three or more primary circuits may be connected in series or in parallel to constitute secondary circuits.

### SECOND MODIFIED EXAMPLE

As in a second modified example illustrated in FIG. 9B, two primary circuits disposed symmetrically with each other with respect to a center of cylindrical body 11 along the axis (X-axis) may constitute secondary circuits. In the configuration illustrated in FIG. 9B, six thermoelectric converters 12 arranged along the periphery are connected in series by feeder cables 22 to constitute a primary circuit, and two each of primary circuits disposed symmetrically with each other with respect to the center of cylindrical body 11 along the axis (X-axis) are connected by feeder cables 24 in series to constitute the secondary circuit. In other words, twelve thermoelectric converters 12 in total are connected in series to constitute the secondary circuit, and driver 32 applies voltages individually to the secondary circuits.

According to the configuration of the second modified example, the power feed control can be performed for each set of thermoelectric converters 12 at positions symmetry with each other with respect to the center of cylindrical body 11 along the axis. This, therefore, enables smooth control such that thermoelectric converters 12 included in the range of the width of the target paper for printing are operated and thermoelectric converters 12 not included in the range of the width of the target paper for printing are not operated. Also, according to the configuration of the second modified example, the number of feeder cables drawn from cylindrical body 11 to driver 32 may be smaller than those in the exemplary embodiment described above.

It should be noted that although two primary circuits disposed symmetrically with each other with respect to the center of cylindrical body 11 along the axis (X-axis) are connected in series to constitute the secondary circuit in the configuration illustrated in FIG. 9B. Two primary circuits disposed symmetrically with each other with respect to the center of cylindrical body 11 along the axis (X-axis) may be connected in parallel to constitute the secondary circuit. Alternatively, a plurality of sets of the primary circuits disposed symmetrically with each other with respect to the center of cylindrical body 11 along the axis (X-axis) may be connected in series or in parallel to constitute secondary circuits.

In the second modified example, the case in which two primary circuits are connected in series to constitute the secondary circuit, that is, the case where an even number of the primary circuits is provided has been described. However, when an odd number of primary circuits is employed, a single primary circuit which cannot constitute the secondary circuit may be disposed at the center of cylindrical body 11 along the axis (X-axis), or may be disposed on an exhaust side of cylindrical body 11 along the axis (X-axis). In the case where the single primary circuit is disposed at the center of cylindrical body 11 along the axis (X-axis), the cooling capacity at the central portion of cylindrical body 11, which requires the largest amount of heat absorption, may be improved. Alternatively, in a case where the single primary circuit is disposed on the exhaust side of cylindrical body 11 along the axis (X-axis), the primary circuit is disposed at a position where the temperature of cooling air passing through the interior of cylindrical body 11 is highest. Therefore, cooling efficiency of cooling unit 10 may be enhanced.

### THIRD MODIFIED EXAMPLE

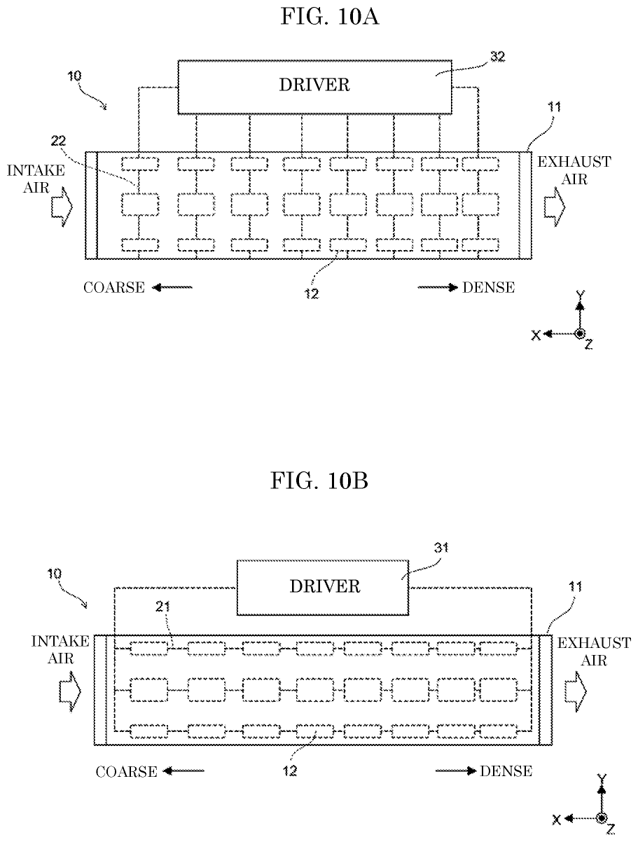

As illustrated in FIG. 10A, in a third modified example, arrangement of thermoelectric converters 12 along the axis of cylindrical body 11 is different from that of the exemplary embodiment described above. Specifically, in the third modified example, thermoelectric converters 12 are disposed more densely on a portion at the downstream side of cooling air flowed along the axis (X-axis) of cylindrical body 11 than on a portion at the upstream side. In the third modified example as well, thermoelectric converters 12 are arranged along the periphery and also along the axis.

With the arrangement of thermoelectric converters 12 in this manner, the cooling effect for cylindrical body 11 is higher at the downstream side of cooling air than that at the upstream side. Therefore, the temperature of the cooling air rises on the downstream side due to exhaust heat from thermoelectric converters 12. Accordingly, even when a cooling capacity of thermoelectric converters 12 on the downstream side is lowered compared with the upstream side, the cooling effect applied to cylindrical body 11 may be made substantially equal along the axis of cylindrical body 11. Therefore, the printing object can be cooled substantially equally.

It should be noted that the temperature gradient of cylindrical body 11 is suppressed by the arrangement of thermoelectric converters 12 in the third modified example, and thus the value of the voltage to be applied to thermoelectric converters 12 does not have to be adjusted as in the case illustrated in FIG. 7B. In the third modified example as well, the connecting state of the feeder cables may be modified to the connecting state illustrated in FIGS. 9A and 9B. The density distribution of thermoelectric converters 12 along the axis is not limited to the mode illustrated in FIG. 10A. Thermoelectric converters 12 need only to be disposed densely on a portion at the downstream side of the cooling air flowed along the axis than on a portion at the upstream side.

### FOURTH MODIFIED EXAMPLE 4

It should be noted that when thermoelectric converters 12 are disposed as illustrated in FIG. 10A, a configuration in which eight thermoelectric converters 12 arranged along the axis (X-axis) of cylindrical body 11 are connected in series by feeder cables 21 may be employed as a fourth modified example illustrated in FIG. 10B. This connecting state is the same as the connecting state of the comparative example illustrated in FIG. 5A. In this connecting state as well, in the same manner as the third modified example, the temperature of the cooling air rises on the downstream side due to exhaust heat from thermoelectric converters 12. Accordingly, even when a cooling capacity of thermoelectric converters 12 on the downstream side is lowered compared with the upstream side, the cooling effect applied to cylindrical body 11 may be made substantially equal along the axis of cylindrical body 11.

However, according to the connecting state of the fourth modified example, the problem of dew condensation due to excessive cooling described with reference to FIG. 5C or the problem of power loss still remains. Therefore, in order to solve these problems, preferably the connecting state in which thermoelectric converters 12 arranged along the periphery are connected in series is used as in the third modified example.

### FIFTH MODIFIED EXAMPLE

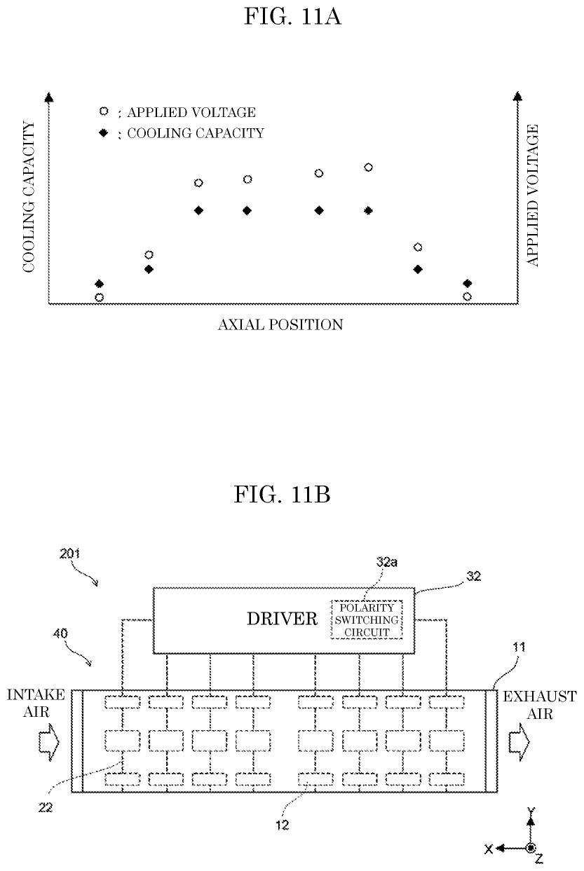

Alternatively, as illustrated in FIG. 11A, driver 32 sets a voltage to be applied to thermoelectric converters 12 positioned out of a range of the width of printing paper P2 along the axis (X-axis) of cylindrical body 11 to be lowered step by step toward the end portion of cylindrical body 11 along the axis from thermoelectric converters 12 positioned within the range of the width of printing paper P2. Accordingly, even in a case where a mounting mechanism for mounting cooling unit 10 to printer 1 is provided at the end portion of cylindrical body 11 and heat from the mounting mechanism is absorbed by thermoelectric converters 12, power consumption may be suppressed while maintaining constant cooling efficiency by making thermoelectric converters 12 positioned out of the range of the width of printing paper P2 function to a degree that can compensate for the absorbed heat.

### SIXTH MODIFIED EXAMPLE

In the exemplary embodiment descried above, the configuration as the cooling device has been described. However, usage as a heating device is also possible by switching the polarity of the voltage feed terminal of driver 32 in FIG. 6B. By mounting the heating device as a heating roller on printer 1, heating of cylindrical body 11 is also possible.

When printer 1 is used in cold areas, the temperature of cooling unit 10 may not reach a predetermined temperature or more when the power of printer 1 is turned ON. In such a case, by using cooling unit 10 as a heating roller, cylindrical body 11 may be rapidly brought to a temperature close to the proper temperature. Consequently, time needed until the start of printing after the power of printer 1 is turned ON may be reduced.

Alternatively, by disposing polarity switching circuit 32a configured to electrically change the polarity of the voltage feed terminal of driver 32 as illustrated in FIG. 11B, temperature control device 201 capable of cooling and heating cylindrical body 11 is also achieved. Temperature control device 201 has the same configuration as that illustrated in FIG. 7A except that driver 32 includes polarity switching circuit 32a. In this case, cylindrical body 11, thermoelectric converters 12, and feeder cables 22 constitute temperature control unit 40. Temperature control device 201 includes temperature control unit 40 and driver 32. Driver 32 supplies voltages to respective circuits including six thermoelectric converters 12 arranged along the periphery of cylindrical body 11 and connected by feeder cables 22. Driver 32 includes polarity switching circuit 32a in an interior thereof. Polarity switching circuit 32a reverses the polarities of the voltages to be supplied to the respective circuits by electrically changing the polarity of voltage feed terminal of driver 32. Thermoelectric converters 12 of the respective circuits apply a cooling effect or a heating effect to cylindrical body 11 depending on the polarities of the voltages to be supplied to the respective circuits.

In this case, temperature control device 201 is mounted on printer 1 instead of cooling device 101 illustrated in FIG. 8A. Polarity switching circuit 32a sets the polarity of voltages to be supplied to the respective circuits of temperature control unit 40 in accordance with a control signal form controller 108.

It should be noted that, although polarity switching circuit 32a is included in driver 32 in the configuration of FIG. 11B, polarity switching circuit 32a does not necessarily have to be included in driver 32, and needs only to be configured such that the polarities of the voltages to be applied to the respective circuits can be electrically changed. Temperature control unit 40 illustrated in FIG. 11B may have the same configuration as those in the first to third modified examples illustrated in FIGS. 9A to 10A.

### OTHER MODIFIED EXAMPLE

Cooling device 101 including cooling unit 10, feeder cables 22 to 24, and driver 32 does not necessarily have to be used for printer 1, and may be used for other apparatuses that require cooling. In this case, the shape of cylindrical body 11 when seen in the X-axis direction does not necessarily have to be circular, and may be modified to, for example, a rounded square as needed depending on demand on the apparatus side in which cooling device 101 is used.

In addition, thermoelectric converters 12 do not necessarily have to be mounted on the inner peripheral surface of cylindrical body 11, and may be mounted on, for example, the outer peripheral surface of cylindrical body 11, which may be changed as needed depending on the demand on the apparatus side in which cooling device 101 is used. In the same manner, arrangement layout of thermoelectric converters 12 or the number of thermoelectric converters 12 to be disposed may also be changed as needed. A mounting structure of thermoelectric converters 12 with respect to cylindrical body 11 is not limited to the mounting structure illustrated in FIGS. 3A and 3B, and may be changed variously. The cooling object may also be changed to paper, cloth, or the like used for printing, or may be changed variously.

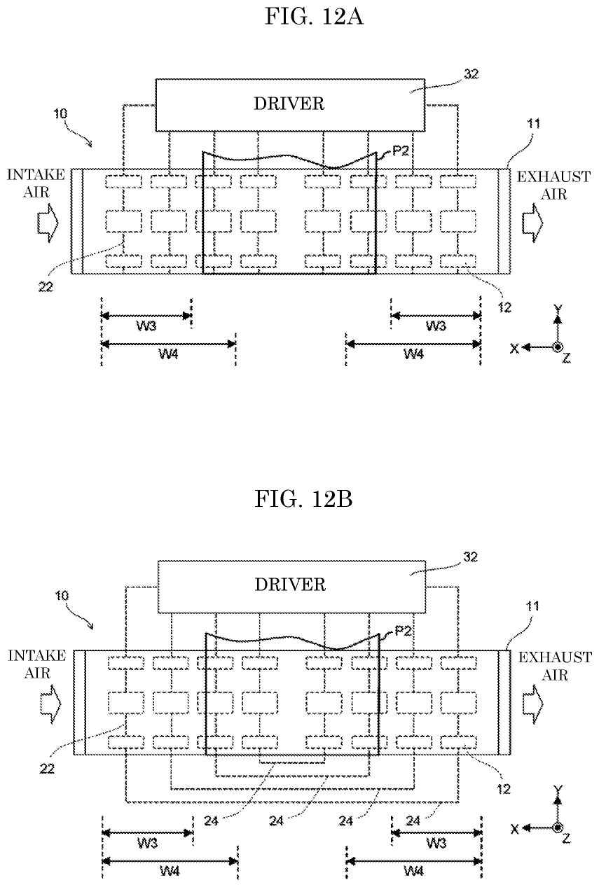

FIG. 12A is a plan view schematically illustrating a conveying process for printing paper in a cooling unit according to a sixth modified example. FIG. 12B is a plan view schematically illustrating a conveying process for printing paper in a cooling unit according to the second modified example. It should be noted that a state in which printing paper P2 is seen through is illustrated.

When it is determined that printing paper P2 having a smaller width is supplied to cooling unit 10 in the flowchart shown in FIG. 8B, controller 108 controls driver 32 to drive only thermoelectric converters 12 included in the central region excluding regions W3 among thermoelectric converters 12 disposed on cooling unit 10. In the case of cooling unit 10 illustrated in FIGS. 12A and 12B, only four rows of thermoelectric converters 12 positioned in the central region of cylindrical body 11 along the axis (X-axis) of cylindrical body 11 are driven. Alternatively, controller 108 controls driver 32 to drive only thermoelectric converters 12 included in the central region excluding regions W4 among thermoelectric converters 12 disposed on cooling unit 10.

In other words, driver 32 sets a voltage to be applied to thermoelectric converters 12 corresponding to printing paper P2 along the axis (X-axis) of cylindrical body 11 to be higher than a voltage for thermoelectric converters 12 not corresponding to printing paper P2. Alternatively, driver 32 sets a voltage to be supplied to thermoelectric converters 12 positioned in a first region along the axis (X-axis) of cylindrical body 11 to be higher than that for the thermoelectric converters positioned in the second regions. Accordingly, the object can be cooled efficiently and stably.

At this time, thermoelectric converters 12 included in the central region excluding regions W3 correspond to the thermoelectric converters positioned in the first region, and thermoelectric converters 12 included in regions W3 correspond to the thermoelectric converters positioned in the second regions. Alternatively, thermoelectric converters 12 included in the central region excluding regions W4 correspond to the thermoelectric converters positioned in the first region, and thermoelectric converters 12 included in regions W4 correspond to the thermoelectric converters positioned in the second regions. In this manner, cylindrical body 11 includes the first region and the second regions, and the second regions are positioned at both ends of the first region.

For example, when printer 1 is used in warm areas, and the temperature at a place where printer 1 is placed reaches a predetermined temperature, only four rows of thermoelectric converters 12 positioned in the central region of cylindrical body 11 are driven. Accordingly, target paper for printing can be efficiently cooled while suppressing an occurrence of dew condensation on cylindrical body 11.

In addition, when printer 1 is used in cold areas, and the temperature at a place where printer 1 is placed does not reach a predetermined temperature, only two rows of thermoelectric converters 12 positioned in the central region of cylindrical body 11 are driven. Accordingly, wasted power consumption is avoided while suppressing an occurrence of dew condensation on cylindrical body 11.

Here, controller 108 determines whether target paper for printing set in printer 1 is printing paper P1 or printing paper P2 based on a detection signal from detector 107. When controller 108 automatically determines target paper for printing, a sensor for detecting the width of printing paper is mounted on printer 1, and the sensor is used as detector 107. When controller 108 does not automatically determine target paper for printing, an operator of printer 1 installs an input terminal that allows the operator to input the size of target paper for printing on printer 1, and uses the input terminal as detector 107.

The exemplary embodiment of the present disclosure can be modified in various ways as appropriate within the scope of the technical idea disclosed in the claims.

### REFERENCE MARKS IN THE DRAWINGS

1: printer

10: cooling unit

11: cylindrical body

12: thermoelectric converter

22 to 24: feeder cables

31, 32: driver

32a : polarity switching circuit

40: temperature control unit

101: cooling device

102: paper conveying section (conveying section)

103: printing section

201: temperature control device

1. A cooling device for cooling an object, the cooling device comprising:
a cylindrical body having thermal conductivity;
a plurality of thermoelectric converters arranged along a periphery of the cylindrical body and disposed dispersedly along an axis of the cylindrical body;
a feeder cable connecting two or more thermoelectric converters arranged along the periphery of the cylindrical body in series among the plurality of thermoelectric converters to form each of a plurality of sets of thermoelectric converters, the feeder cable forming a circuit for power feeding of the each of the plurality of sets of thermoelectric converters; and
a driver configured to feed power to the plurality of thermoelectric converters via the feeder cable,
wherein, in response to contact of the object with the cylindrical body, the driver sets a voltage to be supplied to a first set of thermoelectric converters disposed within a range of a width of the object along the axis of the cylindrical body to be higher than a voltage to be supplied to a second set of thermoelectric converters disposed out of the range of the width of the object, the first set of thermoelectric converters and the second set of thermoelectric converters being included in the plurality of sets of thermoelectric converters.

2. The cooling device according to claim 1, wherein the driver stops the power feeding to the second set of thermoelectric converters disposed out of the range of the width of the object.

3. The cooling device according to claim 1, wherein the driver sets a voltage to be supplied to the second set of thermoelectric converters to be lowered from the first set of thermoelectric converters step by step toward an end portion of the cylindrical body along the axis of the cylindrical body.

4. The cooling device according to claim 1, comprising
a secondary circuit constituted by a combination of two circuits respectively corresponding to two sets of thermoelectric converters that are disposed symmetrically with each other with respect to a center along the axis of the cylindrical body, each of the two circuits being the circuit for the power feeding, the two sets of thermoelectric converters being included in the plurality of sets of thermoelectric converters.

5. The cooling device according to claim 1, wherein the driver sets a voltage to be supplied to a third set of thermoelectric converters positioned at a downstream side of cooling air flowing in the cylindrical body along the axis of the cylindrical body to be higher than a voltage to be supplied to a fourth set of thermoelectric converters positioned at an upstream side of the cooling air along the axis of the cylindrical body, the third set of thermoelectric converters and the fourth set of thermoelectric converters being included in the plurality of sets of thermoelectric converters.

6. A temperature control device for controlling a temperature of an object, the temperature control device comprising:
a cylindrical body having thermal conductivity;
a plurality of thermoelectric converters arranged along a periphery of the cylindrical body and disposed dispersedly along an axis of the cylindrical body;
a feeder cable connecting two or more thermoelectric converters arranged along the periphery of the cylindrical body in series among the plurality of thermoelectric converters to form each of a plurality of sets of thermoelectric converters, the feeder cable forming a circuit for power feeding of the each of plurality of sets of thermoelectric converters;
a driver configured to feed power to the plurality of thermoelectric converters via the feeder cable; and
a polarity switching circuit configured to electrically change a power feed polarity for the circuit.

7. A printer comprising:
the cooling device according to claim 1;
a printing section configured to perform printing on a sheet-shaped material to be printed, the sheet-shaped material being the object; and
a conveying section configured to convey the sheet-shaped material to be printed from the printing section to the cooling device.

8. A printer comprising:
the temperature control device according to claim 6;
a printing section configured to perform printing on a sheet-shaped material to be printed, the sheet-shaped material being the object; and
a conveying section configured to convey the sheet-shaped material to be printed from the printing section to the temperature control device.

9. A cooling device comprising:
a cylindrical body having thermal conductivity;
a plurality of thermoelectric converters arranged along a periphery of the cylindrical body and disposed dispersedly along an axis of the cylindrical body;
a feeder cable connecting two or more thermoelectric converters arranged along the periphery of the cylindrical body in series among the plurality of thermoelectric converters to form each of a plurality of sets of thermoelectric converters, the feeder cable forming a circuit for power feeding of the each of plurality of sets of thermoelectric converters;
a driver configured to feed power to the plurality of thermoelectric converters via the feeder cable,
wherein, in response to contact of the object with the cylindrical body, the driver sets a voltage to be supplied to a first set of thermoelectric converters corresponding to a cooling object along an axis of the cylindrical body to be higher than a voltage to be supplied to a second set of thermoelectric converters not corresponding to the cooling object along an axis of the cylindrical body, the first set of thermoelectric converters and the second set of thermoelectric converters being included in the plurality of sets of thermoelectric converters.

10. A cooling device comprising:
a cylindrical body having thermal conductivity;
a plurality of thermoelectric converters arranged along a periphery of the cylindrical body and disposed dispersedly along an axis of the cylindrical body;
a feeder cable connecting two or more thermoelectric converters arranged along the periphery of the cylindrical body in series among the plurality of thermoelectric converters to form each of a plurality of sets of thermoelectric converters, the feeder cable forming a circuit for power feeding of the each of plurality of sets of thermoelectric converters;
a driver configured to feed power to the plurality of thermoelectric converters via the feeder cable, wherein:
the cylindrical body includes a first region and second regions positioned on both ends of the first region along the axis of the cylindrical body, and
the driver sets a voltage to be supplied to a first set of thermoelectric converters positioned in the first region to be higher than a voltage to be supplied to a second set of thermoelectric converters that is positioned in each of the second regions, the first set of thermoelectric converters and the second set of thermoelectric converters being included in the plurality of sets of thermoelectric converters.

11. The cooling device according to claim 10, wherein the driver stops the power feeding to the second set of thermoelectric converters positioned in the each of the second regions.
